(19) United States
(12) Patent Application Publication
(10) Pub. No.: US 2017/0321318 A1
(43) Pub. Date: Nov. 9, 2017

(54) MATERIAL SOURCE ARRANGMENT AND NOZZLE FOR VACUUM DEPOSITION

(71) Applicant: Applied Materials, Inc., Santa Clara, CA (US)

(72) Inventors: Stefan BANGERT, Steinau (DE); Uwe SCHÜßLER, Aschaffenburg (DE); Jose Manuel DIEGUEZ-CAMPO, Hanau (DE)

(21) Appl. No.: 15/524,871

(22) PCT Filed: Nov. 7, 2014
(86) PCT No.: PCT/EP2014/074088

§ 371 Date: May 5, 2017

(51) Int. Cl. C23C 14/24; C23C 14/12; C23C 14/56; C23C 16/455

(52) U.S. Cl. CPC C23C 14/24; C23C 16/45578; C23C 14/12; C23C 14/562

(57) ABSTRACT

A material source arrangement for depositing a material on a substrate in a vacuum deposition chamber is described. The material source arrangement includes a distribution pipe being configured to be in fluid communication with a material source providing the material to the distribution pipe; and at least one nozzle configured for guiding the material provided in the distribution pipe to the vacuum deposition chamber. The nozzle includes a thread for repeatedly connecting and disconnecting the nozzle to the distribution pipe. Further, a deposition apparatus for depositing material on a substrate including a material source arrangement, a nozzle for a material source arrangement, and a method for providing a distribution pipe and a nozzle for a material source arrangement are described.

### TECHNICAL FIELD OF THE INVENTION

Embodiments of the present invention relate to a material source arrangement, a deposition apparatus having a material source arrangement, a nozzle for a material source arrangement, and a method for providing a distribution pipe for a material source arrangement. Embodiments of the present invention particularly relate to a material source arrangement for a vacuum deposition chamber, a vacuum deposition apparatus having a material source arrangement, a nozzle for a material source arrangement for a vacuum deposition chamber, and a method for providing a distribution pipe for a material source arrangement in a vacuum deposition chamber, specifically to a material source, a deposition apparatus, a nozzle, and a method for an evaporation process.

### BACKGROUND OF THE INVENTION

Organic evaporators are a tool for the production of organic light-emitting diodes (OLED). OLEDs are a special type of light-emitting diodes in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angle possible with OLED displays are greater than that of traditional LCD displays because OLED pixels directly emit light and do not use a back light. Therefore, the energy consumption of OLED displays is considerably less than that of traditional LCD displays. Further, the fact that OLEDs can be manufactured onto flexible substrates results in further applications. A typical OLED display, for example, may include layers of organic material situated between two electrodes that are all deposited on a substrate in a manner to form a matrix display panel having individually energizable pixels. The OLED is generally placed between two glass panels, and the edges of the glass panels are sealed to encapsulate the OLED therein.

There are many challenges encountered in the manufacture of such display devices. OLED displays or OLED lighting applications include a stack of several organic materials, which are for example evaporated in vacuum. The organic materials are deposited in a subsequent manner through shadow masks. For the fabrication of OLED stacks with high efficiency the co-deposition or co-evaporation of two or more materials, e.g. host and dopant, leading to mixed/doped layers is desired. Further, it has to be considered that there are several conditions for the evaporation of the very sensitive organic materials.

Different sizes of substrates to be deposited with an evaporated material and different materials to be deposited further cause the manufacturing process for OLEDs to be complicated and time-consuming, and, thus, expensive. For instance, the distribution strategy of the evaporated material for different materials and different substrate sizes is adapted from case to case.

In view of the above, it is an object of embodiments described herein to provide a material source arrangement, a deposition apparatus having a material source arrangement, a nozzle for a material source arrangement, and a method for providing a distribution pipe for a material source arrangement that overcome at least some of the problems in the art.

### SUMMARY OF THE INVENTION

In light of the above, material source arrangement, a deposition apparatus, a nozzle for a distribution pipe, and a method for providing a distribution pipe for a material source arrangement according to the independent claims are provided. Further aspects, advantages, and features of the present invention are apparent from the dependent claims, the description, and the accompanying drawings.

According to one embodiment, a material source arrangement for depositing a material on a substrate in a vacuum deposition chamber is provided. The material source arrangement includes a distribution pipe being configured to be in fluid communication with a material source providing the material to the distribution pipe. Further, the material source arrangement includes at least one nozzle configured for guiding the material provided in the distribution pipe to the vacuum deposition chamber. The nozzle includes a thread for repeatedly connecting and disconnecting the nozzle to the distribution pipe.

According to another embodiment, a deposition apparatus for depositing material on a substrate is provided. The deposition apparatus includes a vacuum chamber; and a material source for providing material to be deposited on the substrate in the vacuum chamber. The deposition apparatus further includes a material source arrangement according to embodiments described herein.

According to a further embodiment, a nozzle for a distribution pipe for depositing material on a substrate in a vacuum deposition chamber is provided. The nozzle is configured for guiding evaporated material in the vacuum deposition apparatus. The nozzle includes the nozzle a directing portion directing the evaporated material into the vacuum deposition chamber; and a connecting portion comprising a thread for exchangeable connection of the nozzle to a distribution pipe.

According to a further embodiment, a method for providing a distribution pipe and a nozzle for a material source arrangement is provided. The method includes providing a material source for evaporating material to be deposited on a substrate in a vacuum deposition chamber; connecting a distribution pipe to the material source for allowing fluid communication between the material source and the distribution pipe; and screwing a first nozzle for guiding evaporated material to a substrate in the vacuum deposition chamber to the distribution pipe.

Embodiments are also directed at apparatuses for carrying out the disclosed methods and include apparatus parts for performing each described method step. The method steps may be performed by way of hardware components, a computer programmed by appropriate software, by any combination of the two or in any other manner. Furthermore, embodiments according to the invention are also directed at methods for operating the described apparatus. It includes method steps for carrying out every function of the apparatus.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIGS. 1a to 1c show a schematic view of a material source arrangement according to embodiments described herein;

FIGS. 2a to 2c show schematic views of a nozzle for a material source arrangement according to embodiments described herein;

FIGS. 3a and 3b show a schematic, sectional view of a distribution pipe for a material source arrangement according to embodiments described herein;

FIG. 4 shows a schematic view of a deposition apparatus with a material source arrangement according to embodiments described herein; and

FIG. 5 shows a flow chart of a method for providing a distribution pipe and a nozzle for a material source arrangement according to embodiments described herein.

### DETAILED DESCRIPTION OF EMBODIMENTS

Reference will now be made in detail to the various embodiments, one or more examples of which are illustrated in the figures. Within the following description of the drawings, the same reference numbers refer to same components. Generally, only the differences with respect to individual embodiments are described. Each example is provided by way of explanation and is not meant as a limitation for further or other embodiments. Further, features illustrated or described as part of one embodiment can be used on or in conjunction with other embodiments to yield yet a further embodiment. It is intended that the description includes such modifications and variations.

Furthermore, in the following description, a material source may be understood as a source providing a material to be deposited on a substrate. In particular, the material source may be configured for providing material to be deposited on a substrate in a vacuum chamber, such as a vacuum deposition chamber or apparatus. According to some embodiments, the material source may provide the material to be deposited on the substrate by being configured to evaporate the material to be deposited. For instance, the material source may include an evaporator or crucible, which evaporates the material to be deposited on the substrate, and which, in particular, releases the evaporated material in a direction towards the substrate or into a distribution pipe of the material source. In some embodiments, the evaporator may stand in fluid communication with a distribution pipe of the material source, e.g. for distributing the evaporated material.

According to some embodiments described herein, the distribution pipe may be understood as a pipe for guiding and distributing the evaporated material. In particular, the distribution pipe may guide the evaporated material from the evaporator to the outlet or openings of the distribution pipe. A linear distribution pipe may be understood as a pipe extending in a first, especially longitudinal, direction. In some embodiments, the linear distribution pipe includes a pipe having the shape of a cylinder, wherein the cylinder may have a circular bottom shape or any other suitable bottom shape.

As used herein, the term “fluid communication” may be understood in that two elements being in fluid communication can exchange fluid via a connection allowing fluid to flow between the two elements. In one example, the elements being in fluid communication may include a hollow structure, through which the fluid may flow. According to some embodiments, at least one of the elements being in fluid communication may be a pipe-like element.

A nozzle as referred to herein may be understood as a device for guiding a fluid, especially for controlling the direction or characteristics of a fluid (such as the rate of flow, speed, shape, and/or the pressure of the fluid that emerges from the nozzle). According to some embodiments described herein, a nozzle may be a device for guiding or directing a vapor, such as a vapor of an evaporated material to be deposited on a substrate. The nozzle may have an inlet for receiving a fluid, an opening (such as a bore or passageway) for guiding the fluid through the nozzle, and an outlet for releasing the fluid. Typically, the opening or passageway of the nozzle may include a defined geometry for achieving the desired direction or characteristic of the fluid flowing through the nozzle. According to some embodiments, a nozzle may be connected to a distribution pipe providing evaporated material and may receive evaporated material from the distribution pipe.

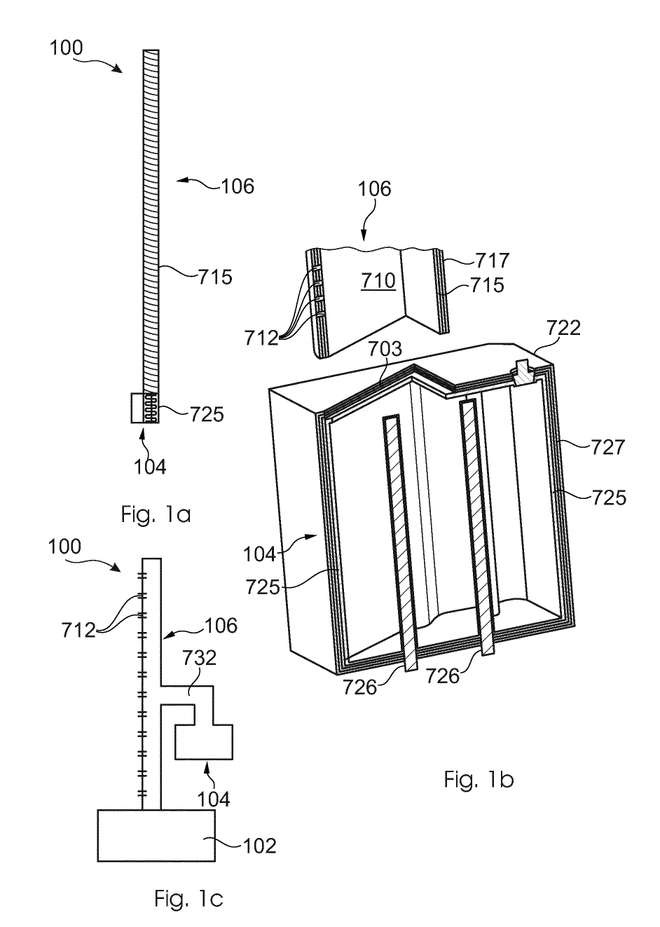

FIGS. 1a to 1c show a material source arrangement 100 according to embodiments described herein. A material source may include a distribution pipe 106 and an evaporation crucible 104 as an evaporator as shown in FIG. 1a. The distribution pipe 106 may stand in fluid communication with the crucible for distributing evaporated material provided by the crucible 104. The distribution pipe can for example be an elongated cube with heating unit 715. The evaporation crucible can be a reservoir for the organic material to be evaporated with a heating unit 725. According to typical embodiments, which can be combined with other embodiments described herein, the distribution pipe 106 provides a line source. Further details of the distribution pipe and the crucible will be discussed in more detail below. According to some embodiments described herein, the material source arrangement 100 further includes a plurality of nozzles for releasing the evaporated material towards the substrate, e.g. nozzles being arranged along at least one line.

According to embodiments described herein, a material source arrangement for depositing a material on a substrate in a vacuum deposition chamber is provided. The material source arrangement includes a distribution pipe configured to be in fluid communication with a material source, which provides the material to the distribution pipe. The material source arrangement according to an embodiment described herein further includes at least one nozzle configured for guiding the material provided in the distribution pipe to the vacuum deposition chamber. The nozzle includes a thread for repeatedly connecting and disconnecting the nozzle to the distribution pipe.

According to some embodiments described herein, the nozzle having a thread for being connected to the distribution pipe may have an inner thread and/or an external thread for being able to repeatedly connect the nozzle to the distribution pipe in particular without destroying the distribution pipe or the nozzle. For instance, a first nozzle having defined characteristics may be connected to the distribution pipe for a first process. After the first process is finished, the first nozzle may be disconnected and a second nozzle may be connected to the distribution pipe for a second process. If the first process is to be performed again, the second nozzle may be disconnected from the distribution pipe and the first nozzle may again be connected to the distribution pipe for performing the first process. According to some embodiments, the distribution pipe may also comprise a thread for exchangeable connection of the nozzle to the distribution pipe, e.g. by fitting to the thread of the nozzle.

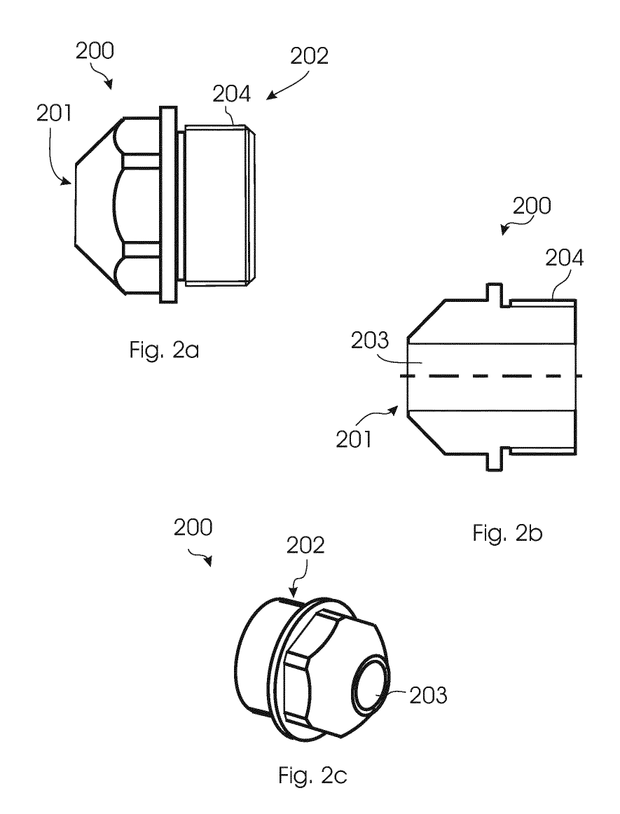

FIGS. 2a to 2c show embodiments of a nozzle according to embodiments described herein. According to embodiments described herein, the nozzle may include a directing portion, which guides the evaporated material to the substrate to be coated. The directing portion may, for instance, be formed and designed so as to cause a desired shape and intensity of the vapor plume released from the nozzle. FIGS. 2a to 2c show a nozzle 200 according to embodiments described herein. The nozzle 200 includes a directing portion 201 and a connecting portion 202 for exchangeable connection of the nozzle to a distribution pipe, such as a distribution pipe as described with respect to FIGS. 1a to 1c. The nozzle 200 includes an opening 203 (or passageway or bore) for guiding the evaporated material through the nozzle. According to some embodiments, the opening (in particular the inner side of the passageway) may be denoted as directing portion of the nozzle. In some embodiments, the outer side of the nozzle may be denoted as connecting portion of the nozzle. In some embodiments, the connecting portion of the nozzle may be made from a material different than the material of the directing portion of the nozzle.

According to embodiments described herein, the connecting portion of the nozzle may be configured for screwing the nozzle to a distribution pipe of a material source arrangement. For instance, the connecting portion of the nozzle may include a thread area 204 as exemplarily shown in FIGS. 2a to 2c. According to some embodiments described herein, the nozzle may include an external thread. The distribution pipe of a material source according to some embodiments described herein may include an internal thread for connecting the nozzle to the distribution pipe. The skilled person will understand that in another embodiment, the nozzle may include an internal thread and the distribution pipe may include an external thread. According to some embodiments, the nozzle or the thread of the nozzle may have an outer diameter of typically between about 5 mm and about 15 mm, more typically between 6 mm and 12 mm, and even more typically between 8 mm and 10 mm

According to some embodiments, which may be combined with other embodiments described herein, the material source arrangement may include a set of nozzles for being (in particular repeatedly) screwable to the distribution pipe for forming an outlet for the evaporated material. In some embodiments, each of the nozzles of the set of nozzles may have at least one of a different inner diameter, a different length to inner diameter ratio, a different design of the passageway (such as geometries including pressure stages, collimator structures, steps, inclinations, and the like), a different design resulting in different shapes of the formed plume of evaporated material, different material(s) from which the nozzle is formed and the like. In some embodiments, the nozzles are arranged in groups, wherein the nozzles of one group provide the same properties (e.g. same inner diameter, the same length to inner diameter ratio, the same design of the passageway), wherein the properties of the different groups differ. According to some embodiments, each nozzle of the set of nozzles, or each group of nozzles, has the same thread, i.e. the same thread size. Each nozzle of the set of nozzles, or each group of nozzles, may repeatedly be connected to the same distribution pipe.

According to some embodiments, which may be combined with other embodiments described herein, the nozzles referred to herein may be made from titanium, or may include titanium. According to some embodiments, the nozzle may include a material having a thermal conductivity value higher than the thermal conductivity value of titanium (e.g. the material may have a thermal conductivity of more than 21 W/mK). For instance, the nozzle according to embodiments described herein may include at least one material of the group consisting of Cu, Ty, Nb, Ti, DLC, and graphite. In some embodiments, which may be combined with other embodiments described herein, the opening or passageway of the nozzle may be coated with Cu, Ty, Nb, Ti, DLC, and graphite. According to embodiments described herein, the nozzle including the above described material characteristics or the above referenced materials may avoid a condensation of the evaporated material in the nozzle. For instance, with the material source and the distribution pipe being heated, the nozzle may be considered as a heat sink, because the nozzle may have a geometry not suitable to be kept at a desired temperature (such as a temperature being 10° C. to 15° C. higher than the evaporation temperature) in a sufficient way. In one example, the nozzle is not heated compared to the distribution pipe. The materials referred to in embodiments described herein may help to keep the nozzle at a temperature avoiding condensation and contamination of the substrate with condensed material.

According to some embodiments described herein, the opening or passageway of the nozzle, through which the evaporated material flows during the evaporation process in order to reach the substrate to be coated, may have a size of typically about 1 mm to about 10 mm, more typically about 1 mm to about 6 mm, and even more typically 2 mm to about 5 mm. According to some embodiments, the dimension of the passageway or opening may refer to the minimum dimension of a cross-section, e.g. the diameter of the passageway or the opening. In one embodiment, the size of the opening or the passageway is measured at the outlet of the nozzle. According to some embodiments described herein, the opening or passageway may be produced in the tolerance zone H7, e.g. produced with a tolerance of about 10 μm to about 18 μm.

According to some embodiments, which may be combined with other embodiments described herein, the nozzles referred to herein may be designed to form a plume having a cosⁿ like shaped profile, wherein n is in particular larger than 4. In one example, the nozzle is designed to form a plume having a cos⁶ like shaped profile. The nozzle achieving a cos⁶ formed plume of evaporated material may be useful if a narrow shape of the plume is desired. For instance, a deposition process including masks for the substrate having small openings (such as openings having a size of about 50 μm and below, for instance 20 μm) may benefit from the narrow cos⁶ shaped plume and the material exploitation may be increased since the plume of evaporated material does not spread on the mask but passes the openings of the mask. According to some embodiments, the nozzle may be designed so that the relation of the length of the nozzle and the size of the passageway of the nozzle stand in a defined relation, such as having a ratio of 2:1 or larger. According to additional or alternative embodiments, the passageway of the nozzle may include steps, inclinations, collimator structure(s) and/or pressure stages for achieving the desired plume shape.

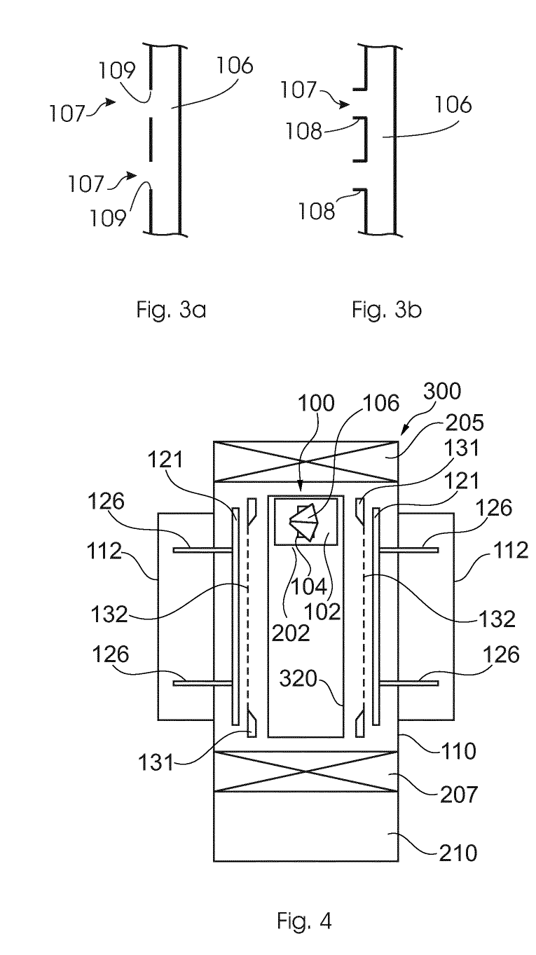

FIGS. 3a and 3b show sectional views of embodiments of a distribution pipe 106 for a material source arrangement according to embodiments described herein. In some embodiments, the distribution pipe may have a connecting area allowing for exchangeable connection of the nozzle to the distribution pipe, such as by providing a thread. FIG. 3a shows a distribution pipe having openings 107, which provide the connecting area allowing for connecting a nozzle, according to embodiments, to the distribution pipe 106. For instance, the openings 107 may be provided having threads at the walls 109. FIG. 3b shows an embodiment of a distribution pipe 106 having extensions 108 around the openings 107 for providing a thread area of the distribution pipe.

Going back to FIGS. 1a to 1c, FIGS. 1a to 1c show a material source arrangement, for which the above described nozzles according to embodiments herein may be used. According to some embodiments, which can be combined with other embodiments described herein, the nozzles of the distribution pipe may be adapted for releasing the evaporated material in a direction different from the length direction of the distribution pipe, such as a direction being substantially perpendicular to the length direction of the distribution pipe. According to some embodiments, the nozzles are arranged to have a main evaporation direction to be horizontal +−20°. According to some specific embodiments, the evaporation direction can be oriented slightly upward, e.g. to be in a range from horizontal to 15° upward, such as 3° to 7° upward. Correspondingly, the substrate can be slightly inclined to be substantially perpendicular to the evaporation direction. Undesired particle generation can be reduced. However, the nozzle and the material source arrangement according to embodiments described herein may also be used in a deposition apparatus, which is configured for depositing material on a horizontally oriented substrate.

In one example, the length of the distribution pipe 106 corresponds at least to the height of the substrate to be deposited in the deposition apparatus. In many cases, the length of the distribution pipe 106 will be longer than the height of the substrate to be deposited, at least by 10% or even 20%. A uniform deposition at the upper end of the substrate and/or the lower end of the substrate can be provided.

According to some embodiments, which can be combined with other embodiments described herein, the length of the distribution pipe can be 1.3 m or above, for example 2.5 m or above. According to one configuration, as shown in FIG. 1a, the evaporation crucible 104 is provided at the lower end of the distribution pipe 106. The organic material is evaporated in the evaporation crucible 104. The vapor of organic material enters the distribution pipe 106 at the bottom of the distribution pipe and is guided essentially sideways through the plurality of nozzles in the distribution pipe, e.g. towards an essentially vertical substrate.

FIG. 1b shows an enlarged schematic view of a portion of the material source, wherein the distribution pipe 106 is connected to the evaporation crucible 104. A flange unit 703 is provided, which is configured to provide a connection between the evaporation crucible 104 and the distribution pipe 106. For example the evaporation crucible and the distribution pipe are provided as separate units, which can be separated and connected or assembled at the flange unit, e.g. for operation of the material source.

The distribution pipe 106 has an inner hollow space 710. A heating unit 715 may be provided to heat the distribution pipe. Accordingly, the distribution pipe 106 can be heated to a temperature such that the vapor of the organic material, which is provided by the evaporation crucible 104, does not condense at an inner portion of the wall of the distribution pipe 106.

For instance, the distribution pipe may be held at a temperature, which is typically about 1° C. to about 20° C., more typically about 5° C. to about 20° C., and even more typically about 10° C. to about 15° C. higher than the evaporation temperature of the material to be deposited on the substrate. Two or more heat shields 717 are provided around the tube of the distribution pipe 106.

During operation, the distribution pipe 106 may be connected to the evaporation crucible 104 at the flange unit 703. The evaporation crucible 104 is configured to receive the organic material to be evaporated and to evaporate the organic material. According to some embodiments, the material to be evaporated may include at least one of ITO, NPD, Alq₃, Quinacridone, Mg/AG, starburst materials, and the like. FIG. 1b shows a cross-section through the housing of the evaporation crucible 104. A refill opening is provided, for example, at an upper portion of the evaporation crucible, which can be closed using a plug 722, a lid, a cover or the like for closing the enclosure of evaporation crucible 104.

An outer heating unit 725 is provided within the enclosure of the evaporation crucible 104. The outer heating element can extend at least along a portion of the wall of the evaporation crucible 104. According to some embodiments, which can be combined with other embodiments described herein, one or more central heating elements 726 can additionally or alternatively be provided. FIG. 1b shows two central heating elements 726. According to some implementations, the evaporation crucible 104 can further include a shield 727.

According to some embodiments, as exemplarily shown with respect to FIGS. 1a to 1b, the evaporation crucible 104 is provided at a lower side of the distribution pipe 106. According to yet further embodiments, which can be combined with other embodiments described herein, a vapor conduit 732 can be provided to the distribution pipe 106 at the central portion of the distribution pipe or at another position between the lower end of the distribution pipe and the upper end of the distribution pipe. FIG. 1c illustrates an example of the material source having a distribution pipe 106 and a vapor conduit 732 provided at a central portion of the distribution pipe. Vapor of organic material is generated in the evaporation crucible 104 and is guided through the vapor conduit 732 to the central portion of the distribution pipes 106. The vapor exits the distribution pipe 106 through a plurality of nozzles 712, which may be nozzles as described with respect to FIGS. 2a to 2c. According to yet further embodiments, which can be combined with other embodiments described herein, two or more vapor conduits 732 can be provided at different positions along the length of the distribution pipe 106. The vapor conduits 732 can either be connected to one evaporation crucible 104 or to several evaporation crucibles 104. For example, each vapor conduit 732 can have a corresponding evaporation crucible 104. Alternatively, the evaporation crucible 104 can be in fluid communication with two or more vapor conduits 732, which are connected to the distribution pipe 106.

As described herein, the distribution pipe can be a hollow cylinder. The term cylinder can be understood as commonly accepted as having a circular bottom shape, a circular upper shape and a curved surface area or shell connecting the upper circle and the little lower circle. According to further additional or alternative embodiments, which can be combined with other embodiments described herein, the term cylinder can further be understood in the mathematical sense as having an arbitrary bottom shape, an identical upper shape and a curved surface area or shell connecting the upper shape and the lower shape. Accordingly, the cylinder does not necessarily need to have a circular cross-section. Instead, the base surface and the upper surface can have a shape different from a circle.

FIG. 4 shows a deposition apparatus 300 in which a material source arrangement or a nozzle according to embodiments described herein may be used. The deposition apparatus 300 includes a material source 100 in a position in a vacuum chamber 110. According to some embodiments, which can be combined with other embodiments described herein, the material source is configured for a translational movement and a rotation around an axis. The material source 100 has one or more evaporation crucibles 104 and one or more distribution pipes 106. Two evaporation crucibles and two distribution pipes are shown in FIG. 4. The distribution pipes 106 are supported by the support 102. Further, according to some embodiments, the evaporation crucibles 104 can also be supported by the support 102. Two substrates 121 are provided in the vacuum chamber 110. Typically, a mask 132 for masking of the layer deposition on the substrate can be provided between the substrate and the material source 100. Organic material is evaporated from the distribution pipes 106. According to some embodiments, the material source may include a material source arrangement as shown in FIGS. 1a to 1c.

According to embodiments described herein, the substrates are coated with organic material in an essentially vertical position. The view shown in FIG. 4 is a top view of an apparatus including the material source 100. Typically, the distribution pipe is a vapor distribution showerhead, particularly a linear vapor distribution showerhead. The distribution pipe provides a line source extending essentially vertically. According to embodiments described herein, which can be combined with other embodiments described herein, essentially vertically is understood particularly when referring to the substrate orientation, to allow for a deviation from the vertical direction of 20° or below, e.g. of 10° or below. The deviation can be provided for example because a substrate support with some deviation from the vertical orientation might result in a more stable substrate position. Yet, the substrate orientation during deposition of the organic material is considered essentially vertical, which is considered different from the horizontal substrate orientation. The surface of the substrates is typically coated by a line source extending in one direction corresponding to one substrate dimension and a translational movement along the other direction corresponding to the other substrate dimension. According to other embodiments, the deposition apparatus may be a deposition apparatus for depositing material on an essentially horizontally oriented substrate. For instance, coating of a substrate in a deposition apparatus may be performed in an up or down direction.

FIG. 4 illustrates an embodiment of a deposition apparatus 300 for depositing organic material in a vacuum chamber 110. The material source 100 is provided in the vacuum chamber 110 on a track, e.g. a looped track or linear guide 320. The track or the linear guide 320 is configured for the translational movement of the material source 100. According to different embodiments, which can be combined with other embodiments described herein, a drive for the translational movement can be provided in the material source 100, at the track or linear guide 320, within the vacuum chamber 110 or a combination thereof. FIG. 4 shows a valve 205, for example a gate valve. The valve 205 allows for a vacuum seal to an adjacent vacuum chamber (not shown in FIG. 4). The valve can be opened for transport of a substrate 121 or a mask 132 into the vacuum chamber 110 or out of the vacuum chamber 110.

According to some embodiments, which can be combined with other embodiments described herein, a further vacuum chamber, such as maintenance vacuum chamber 210 is provided adjacent to the vacuum chamber 110. Typically, the vacuum chamber 110 and the maintenance vacuum chamber 210 are connected with a valve 207. The valve 207 is configured for opening and closing a vacuum seal between the vacuum chamber 110 and the maintenance vacuum chamber 210. The material source 100 can be transferred to the maintenance vacuum chamber 210 while the valve 207 is in an open state. Thereafter, the valve can be closed to provide a vacuum seal between the vacuum chamber 110 and the maintenance vacuum chamber 210. If the valve 207 is closed, the maintenance vacuum chamber 210 can be vented and opened for maintenance of the material source 100 without breaking the vacuum in the vacuum chamber 110.

Two substrates 121 are supported on respective transportation tracks within the vacuum chamber 110 in the embodiment shown in FIG. 4. Further, two tracks for providing masks 132 thereon are provided. Coating of the substrates 121 can be masked by respective masks 132. According to typical embodiments, the masks 132, i.e. a first mask 132 corresponding to a first substrate 121 and a second mask 132 corresponding to a second substrate 121, are provided in a mask frame 131 to hold the mask 132 in a predetermined position.

According to some embodiments, which can be combined with other embodiments described herein, a substrate 121 can be supported by a substrate support 126, which is connected to an alignment unit 112. An alignment unit 112 can adjust the position of the substrate 121 with respect to the mask 132. FIG. 4 illustrates an embodiment where the substrate support 126 is connected to an alignment unit 112. Accordingly, the substrate is moved relative to the mask 132 in order to provide for a proper alignment between the substrate and the mask during deposition of the organic material. According to a further embodiment, which can be combined with other embodiments described herein, alternatively or additionally the mask 132 and/or the mask frame 131 holding the mask 132 can be connected to the alignment unit 112. In some embodiments, either the mask can be positioned relative to the substrate 121 or the mask 132 and the substrate 121 can both be positioned relative to each other. The alignment units 112, which are configured for adjusting the position between a substrate 121 and a mask 132 relative to each other, allow for a proper alignment of the masking during the deposition process, which is beneficial for high quality, LED display manufacturing or OLED display manufacturing.

As shown in FIG. 4, the linear guide 320 provides a direction of the translational movement of the material source 100. On both sides of the material source 100 a mask 132 is provided. The masks 132 can in some embodiments extend essentially parallel to the direction of the translational movement. Further, the substrates 121 at the opposing sides of the material source 100 can also extend essentially parallel to the direction of the translational movement. According to typical embodiments, a substrate 121 can be moved into the vacuum chamber 110 and out of the vacuum chamber 110 through valve 205. A deposition apparatus 300 can include a respective transportation track for transportation of each of the substrates 121. For example, the transportation track can extend parallel to the substrate position shown in FIG. 4 and into and out of the vacuum chamber 110.

Typically, further tracks are provided for supporting the mask frames 131 and the masks 132. Accordingly, some embodiments, which can be combined with other embodiments described herein, can include four tracks within the vacuum chamber 110. In order to move one of the masks 132 out of the chamber, for example for cleaning of the mask, the mask frame 131 and the mask can be moved onto the transportation track of the substrate 121. The respective mask frame can then exit or enter the vacuum chamber 110 on the transportation track for the substrate. Even though it would be possible to provide a separate transportation track into and out of the vacuum chamber 110 for the mask frames 131, the costs of ownership of a deposition apparatus 200 can be reduced if only two tracks, i.e. transportation tracks for a substrate, extend into and out of the vacuum chamber 110 and, in addition, the mask frames 131 can be moved onto a respective one of the transportation tracks for the substrate by an appropriate actuator or robot.

FIG. 4 illustrates an exemplary embodiment of the material source 100. The material source 100 includes a support 102. The support 102 is configured for the translational movement along the linear guide 320. The support 102 supports two evaporation crucibles 104 and two distribution pipes 106 provided over the evaporation crucible 104. The vapor generated in the evaporation crucible can move upwardly and out of the one or more outlets of the distribution pipe.

According to embodiments described herein, a material source includes one or more evaporation crucibles and one or more distribution pipes, wherein a respective one of the one or more distribution pipes can be in fluid communication with the respective one of the one or more evaporation crucibles. Various applications for OLED device manufacturing include processing steps, wherein two or more organic materials are evaporated simultaneously. Accordingly, as for example shown in FIG. 4, two distribution pipes and corresponding evaporation crucibles can be provided next to each other. Accordingly, the material source 100 may also be referred to as a material source array, e.g. wherein more than one kind of organic material is evaporated at the same time. As described herein, the material source array itself can be referred to as a material source for two or more organic materials, e.g. the material source array may be provided for evaporating and depositing three materials onto one substrate.

The one or more outlets of the distribution pipe may include one or more nozzles, which can, e.g., be provided in a showerhead or another vapor distribution system. The nozzles provided for the distribution pipe described herein may be nozzles as described in embodiments herein, such as nozzles described with respect to FIGS. 2a to 2c. A distribution pipe can be understood herein, to include an enclosure having openings such that the pressure in the distribution pipe is higher than that outside of the distribution pipe (e.g. a vacuum chamber, where the distribution pipe is arranged), for example by at least one order of magnitude. In one example, the pressure in the distribution pipe may be between about 10⁻² to about 10⁻¹ mbar, or between about 10-² to about 10-³ mbar. According to some embodiments, the vacuum chamber may provide a pressure of about 10⁻⁵ to about 10⁻⁷ mbar

According to embodiments described herein, which can be combined with other embodiments described herein, the rotation of the distribution pipe can be provided by a rotation of an evaporator control housing, on which at least the distribution pipe is mounted. Additionally or alternatively, the rotation of the distribution pipe can be provided by moving the material source along the curved portion off a looped track. Typically, also the evaporation crucible is mounted on the evaporator control housing. Accordingly, the material sources include a distribution pipe and an evaporation crucible, which may both be rotatably mounted, e.g. together.

According to some embodiments, which can be combined with other embodiments described herein, the distribution pipe may have a plurality of openings, such as a reception for a nozzle array. According to some embodiments, which can be combined with other embodiments described herein, the distribution pipe or evaporation tube can be designed in a triangular shape, so that it is possible to bring the openings or the nozzle arrays as close as possible to each other. Bringing the nozzles as close as possible to each other allows, for instance, for achieving an improved mixture of the different organic materials, e.g. for the case of the co-evaporation of two, three or even more different organic materials. An example of a distribution pipe having a triangular-like shape can be seen in FIG. 4.

According to embodiments described herein, the width of the outlet side of the distribution pipe (which is the side of the distribution pipe including the openings) is 30% or less of the maximum dimension of the cross-section. In light thereof, the openings of the distribution pipes or the nozzles of neighboring distribution pipes can be provided at a smaller distance. The smaller distance improves mixing of organic materials, which are evaporated next to each other. Yet further, additionally or alternatively, and independent of the improved mixing of organic materials, the width of the wall facing the substrate in an essentially parallel manner can be reduced. Correspondingly, the surface area of a wall facing a substrate in an essentially parallel manner can be reduced. The arrangement reduces the heat load provided to a mask or substrate, which are supported in the deposition area or slightly before the deposition area.

Additionally or alternatively, in light of the triangular shape of the material source, the area, which radiates towards the mask, is reduced. Additionally, a stack of metal plates, for example up to 10 metal plates, can be provided to reduce the heat transfer from the material source to the mask. According to some embodiments, which can be combined with other embodiments described herein, the heat shields or metal plates can be provided with orifices for the nozzles and may be attached to at least the front side of the source, i.e. the side facing the substrate.

Although the embodiment shown in FIG. 4 provides a deposition apparatus with a movable source, the skilled person may understand that the above described embodiments may also be applied in deposition apparatuses in which the substrate is moved during processing. For instance, the substrates to be coated may be guided and driven along stationary material sources.

According to some embodiments, which may be combined with other embodiments described herein, a material deposition arrangement for depositing one, two or more evaporated materials on a substrate in a vacuum chamber is provided. The material deposition arrangement includes a first material source including a first material evaporator configured for evaporating a first material to be deposited on the substrate. The first material source further includes a first distribution pipe including a first distribution pipe housing, wherein the first distribution pipe is in fluid communication with the first material evaporator, wherein the material source further includes a plurality of first nozzles in the first distribution pipe housing. Typically, one or more nozzles of the plurality of first nozzles includes an opening length and an opening size, wherein the length to size ratio of the one or more nozzles of the plurality of first nozzles is equal to or larger than 2:1. The material deposition apparatus includes a second material source including a second material evaporator configured for evaporating a second material to be deposited on the substrate. The second material source further includes a second distribution pipe including a second distribution pipe housing, wherein the second distribution pipe is in fluid communication with the second material evaporator. The second material source further includes a plurality of second nozzles in the second distribution pipe housing. According to embodiments described herein, a distance between a first nozzle of the plurality of first nozzles and a second nozzle of the plurality of second nozzles is equal to or less than 30 mm. According to some embodiments, the first material and the second material may be the same material.

According to further embodiments, which may be combined with other embodiments described herein, a material deposition arrangement for depositing one, two or more evaporated materials on a substrate in a vacuum chamber is provided. The material deposition arrangement includes a first material source including a first material evaporator configured for evaporating a first material to be deposited on the substrate. The first material source further includes a first distribution pipe including a first distribution pipe housing, wherein the first distribution pipe is in fluid communication with the first material evaporator; Further, the first material source includes a plurality of first nozzles in the first distribution pipe housing, wherein one or more nozzles of the plurality of first nozzles comprises an opening length and an opening size and is configured to provide a first distribution direction. The length to size ratio of the one or more nozzles of the plurality of first nozzles is equal to or larger than 2:1. The material deposition arrangement further includes a second material source including a second material evaporator configured for evaporating a second material to be deposited on the substrate; and a second distribution pipe: the second distribution pipe includes a second distribution pipe housing, wherein the second distribution pipe is in fluid communication with the second material evaporator. The second material source further includes a plurality of second nozzles in the second distribution pipe housing, wherein one or more of the second nozzles is configured to provide a second distribution direction. According to embodiments described herein, the first distribution direction of the one or more of the plurality of first nozzles and the second distribution direction of the one or more of the plurality of second nozzles are arranged parallel to each other or are arranged with a deviation of up to 5° from the parallel arrangement. According to some embodiments, the first material and the second material may be the same material.

According to some embodiments, which may be combined with other embodiments described herein, a distribution pipe for depositing evaporated material on a substrate in a vacuum chamber is provided. The distribution pipe includes a distribution pipe housing and a nozzle in the distribution pipe housing. The nozzle includes an opening length and an opening size, wherein the length to size ratio of the nozzle is equal to or larger than 2:1. Further, the nozzle includes a material chemically inert to evaporated organic material. In one example, evaporated organic material may have a temperature of about 150° C. and about 650° C.

Embodiments described herein particularly relate to deposition of organic materials, e.g. for OLED display manufacturing on large area substrates. According to some embodiments, large area substrates or carriers supporting one or more substrates, i.e. large area carriers, may have a size of at least 0.174 m². For instance, the deposition apparatus may be adapted for processing large area substrates, such as substrates of GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. According to typical embodiments, which can be combined with other embodiments described herein, the substrate thickness can be from 0.1 to 1.8 mm and the holding arrangement for the substrate, can be adapted for such substrate thicknesses. However, particularly the substrate thickness can be about 0.9 mm or below, such as 0.5 mm or 0.3 mm, and the holding arrangement is adapted for such substrate thicknesses. Typically, the substrate may be made from any material suitable for material deposition. For instance, the substrate may be made from a material selected from the group consisting of glass (for instance soda-lime glass, borosilicate glass etc.), metal, polymer, ceramic, compound materials, carbon fiber materials or any other material or combination of materials which can be coated by a deposition process.

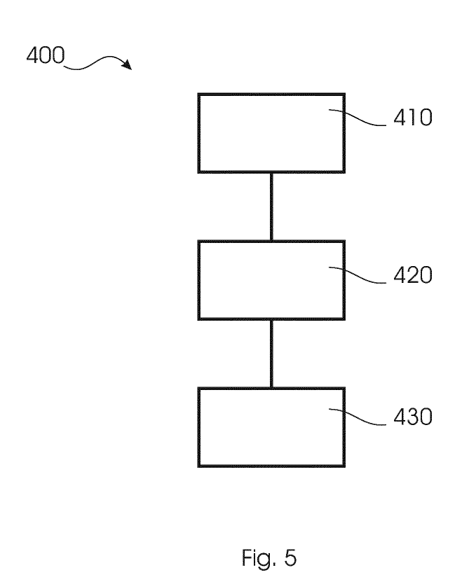

According to embodiments described herein, a method is provided for providing a material source arrangement. The material source arrangement may be a material source arrangement as described with respect to embodiments above and/or may be a material source arrangement, which may be used in a deposition apparatus according to embodiments described herein. A flowchart of a method 400 according to embodiments described herein can be seen in FIG. 5. The method includes in block 410 providing a material source for evaporating material to be deposited on a substrate in a vacuum deposition chamber. According to some embodiments, the material source provided may be a material source as for instance described with respect to FIG. 1 or 3. For instance, the material source may be a source for evaporating organic materials. In one example, the material source may be adapted for evaporating material having typically an evaporation temperature of about 150° to about 650° C., ore typically between about 100° C. and about 500° C. In some embodiments, the material source may be a crucible.

In block 420, the method 400 includes connecting a distribution pipe to the material source for allowing fluid communication between the material source and the distribution pipe. According to some embodiments, the distribution pipe may be a distribution pipe as described in embodiments above, in particular in the embodiments described with respect to FIGS. 1 and 3. In some embodiments, the distribution pipe may for instance have a triangular cross section for being able to use the space in an optimized way. Typically, the distribution pipe includes a connecting area or connecting portion for connecting a nozzle to the distribution pipe. For instance, the connecting area may be adapted for connecting a nozzle as exemplarily shown in FIGS. 2a to 2c to the distribution pipe.

Block 430 includes screwing a nozzle for guiding evaporated material to a substrate in the vacuum deposition chamber to the distribution pipe. In one embodiment, the nozzle shown and described with respect to FIGS. 2a to 2c may be used in block 430 of method 400. According to some embodiments, the method may further include forming a vapor plume having a cos⁶ like shape, as discussed above. In some embodiments, the method may further include choosing a second nozzle from a set of nozzles and replacing the first nozzle by the second nozzle by screwing.

Further, the use of at least one of a material source arrangement according to embodiments described herein, a deposition apparatus having a material source arrangement according to embodiments described herein and a nozzle according to embodiments described herein is described.

While the foregoing is directed to some embodiments, other and further embodiments may be devised without departing from the basic scope thereof, and the scope thereof is determined by the claims that follow.

1. A material source arrangement for depositing a material on a substrate in a vacuum deposition chamber, comprising:
a distribution pipe configured to stand in fluid communication with a material source providing the material to the distribution pipe; and
at least one nozzle configured for guiding the material provided in the distribution pipe to the vacuum deposition chamber, wherein the nozzle comprises a thread for connecting the nozzle to the distribution pipe.

2. The material source arrangement according to claim 1, wherein the nozzle comprises an external thread and the distribution pipe comprises an internal thread for connecting the nozzle.

3. The material source arrangement according to claim 1, wherein the material source is an evaporation crucible and the material source arrangement provides evaporated organic material.

4. The material source arrangement according to claim 1, wherein the distribution pipe is a linear vapor distribution showerhead comprising one or more outlets.

5. The material source arrangement according to claim 1, wherein the distribution pipe comprises one or more outlets for releasing the material in the distribution pipe in a direction different from the length direction of the distribution pipe.

6. The material source arrangement according to claim 4, wherein one nozzle is provided in each outlet of the distribution pipe.

7. The material source arrangement according to claim 1, further comprising a set of nozzles each having at least one of a different inner diameter and a different design resulting in different cosine exponents of the plume of released material.

8. The material source arrangement according to claim 1, wherein the nozzle comprises a material having a thermal conductivity value larger than 21 W/mK.

9. A deposition apparatus for depositing material on a substrate, comprising
a vacuum chamber;
a material source for providing material to be deposited on the substrate in the vacuum chamber; and
a material source arrangement for depositing a material on a substrate in a vacuum deposition chamber, comprising:
a distribution pipe configured to stand in fluid communication with a material source providing the material to the distribution pipe; and
a set of nozzles configured for guiding the material provided in the distribution pipe to the vacuum deposition chamber.

10. The deposition apparatus according to claim 9, comprising
two or more material sources; and
two or more distribution pipes, wherein a first distribution pipe of the two or more distribution pipes is in fluid communication with a first material source of the two or more material sources and a second distribution pipe of the two or more distribution pipes is in fluid communication with a second material source of the two or more material sources.

11. The deposition apparatus according to claim 9, wherein the material source is an evaporation crucible, with which the distribution pipe of the material source arrangement is connected for guiding evaporated material from the evaporation crucible into the vacuum chamber, wherein the nozzle comprises an external thread and the distribution pipe comprises an internal thread for connecting the nozzle to the distribution pipe; and wherein the nozzle of the material source arrangement is arranged for directing the evaporated material towards a substrate in the vacuum chamber.

12. A nozzle for depositing material on a substrate in a vacuum deposition chamber, wherein the nozzle is configured for guiding evaporated material in the vacuum deposition chamber, the nozzle comprising:
a directing portion directing the evaporated material into the vacuum deposition chamber; and
a connecting portion comprising a thread for an exchangeable connection of the nozzle to a distribution pipe.

13. The nozzle according to claim 12, wherein the nozzle has an outer diameter between 5 mm and 15 mm.

14. Method for providing a distribution pipe and a nozzle for a material source arrangement, the method comprising:
providing a material source for evaporating material to be deposited on a substrate in a vacuum deposition chamber;
connecting a distribution pipe to the material source for allowing fluid communication between the material source and the distribution pipe; and
at least one nozzle for guiding evaporated material sideways from the distribution pipe to a substrate in the vacuum deposition chamber.

15. Method according to claim 14, further comprising choosing a second nozzle from a set of nozzles and replacing the first nozzle by the second nozzle by screwing.

16. The material source arrangement of claim 1, wherein the material source is an evaporation crucible, and the evaporation crucible and the distribution pipe are mounted to be rotatable together.

17. The material source arrangement according to claim 1, wherein the distribution pipe extends essentially vertically.

18. The material source arrangement according to claim 1, wherein the material source arrangement is configured for a translational movement and a rotation around an axis.

19. The material source arrangement according to claim 2, wherein the material source arrangement is configured for a translational movement and a rotation around an axis.

20. The deposition apparatus according to claim 15, wherein:
the nozzle comprises an external thread and the distribution pipe comprises an internal thread for connecting the nozzle to the distribution pipe; and
the nozzle of the material source arrangement is arranged for directing the evaporated material sideways towards a substrate while moving laterally in the vacuum chamber.
